(19) United States
(12) Patent Application Publication
(10) Pub. No.: US 2025/0281941 A1
(43) Pub. Date: Sep. 11, 2025

(54) APPARATUS FOR FABRICATING DISPLAY PANEL

(71) Applicant: Samsung Display Co., Ltd., Yongin-Si (KR)

(72) Inventors: Jeong Ho YI, Yongin-si (KR); Yeong Jun KIM, Yongin-si (KR)

(21) Appl. No.: 18/919,447

(22) Filed: Oct. 18, 2024

(30) Foreign Application Priority Data
Mar. 5, 2024 (KR) 10-2024-0031339

(51) Int. Cl. B05C 13/02; B05C 5/02

(52) U.S. Cl. CPC B05C 13/02; B05C 5/02

(57) ABSTRACT

An apparatus for fabricating a display device is provided which comprises a loading plate having a plurality of pattern electrodes arranged in a matrix on a front surface, wherein a fabrication substrate is loaded on the front surface where the plurality of pattern electrodes is arranged, a dispenser for dispensing a liquid dispensing material on the fabrication substrate, and a thin-film coating controller disposed on a rear surface of the loading plate and connected to the plurality of electrodes to supply a high-level pattern voltage to at least one pattern electrode among the plurality of pattern electrodes so that an electric field is formed between the plurality of pattern electrodes, wherein the thin-film coating controller selectively supplies the high-level pattern voltage to the at least one pattern electrode based on pattern information including a type of the dispensing material, a pattern design structure, or a step structure of the fabrication substrate.

### CROSS-REFERENCE TO RELATED APPLICATIONS

This application claims priority to and the benefit of Korean Patent Application No. 10-2024-0031339, filed on Mar. 5, 2024, in the Korean Intellectual Property Office, under 35 U.S.C. 119, the disclosure of which in its entirety is herein incorporated by reference.

### BACKGROUND

### 1. Field of the Disclosure

The present disclosure relates to a method of fabricating a display panel.

### 2. Description of the Related Art

Display devices become more and more important as multimedia technology evolves. In accordance with it, a variety of display devices such as organic light-emitting display devices, liquid-crystal display devices, field-emission display devices, and plasma display devices are currently being used.

Display devices are for displaying images and include a display panel such as an organic light-emitting display panel or a liquid-crystal display panel. For example, an organic light-emitting display panel may include light-emitting diodes (LEDs). Light-emitting diodes may include an organic light-emitting diode using an organic material as a luminescent material, or an inorganic light-emitting diode using an inorganic material as a luminescent material, etc.

To fabricate an image display panel such as an organic light-emitting display panel or a liquid-crystal display panel, it may be required to dispense and print photoresist or organic or inorganic insulating materials on a transparent insulating substrate (hereinafter referred to as fabrication substrate) made of silicon, glass, etc. In doing so, the fabrication substrate is precisely placed on a loading plate, and coating materials such as the photoresist and the organic or inorganic insulating material are dispensed onto the fabrication substrate using a dispenser or an inkjet printer. However, due to differences in surface energy between the loading plate and the fabrication substrate, as well as other fabrication environments, there was a problem with the uniformity of the leveling of the coating materials applied on the fabrication substrate.

### SUMMARY

The present disclosure may provide an apparatus for fabricating a display panel that can form a thin film by uniformly leveling the materials dispensed and coated on a transparent insulating substrate (hereinafter referred to as a fabrication substrate).

The present disclosure may also provide an apparatus for fabricating a display panel that ensures the materials dispensed and coated on a fabrication substrate are selectively formed into a thin film on specific areas of a fabrication substrate, and can form a uniformly leveled thin film in the partial regions of the fabrication substrate by minimizing the influence of the irregularities of the fabrication substrate.

It should be noted that features of the present disclosure are not limited to the above-mentioned feature and other features of the present disclosure will be apparent to those skilled in the art from the following descriptions.

According to an embodiment of the present disclosure, an apparatus for fabricating a display device comprises a loading plate having a plurality of pattern electrodes arranged in a matrix on a front surface, wherein a fabrication substrate is loaded on the front surface of the loading plate where the plurality of pattern electrodes is arranged, at least one dispenser for dispensing a liquid dispensing material on the fabrication substrate, and a thin-film coating controller disposed on a rear surface of the loading plate and connected to the plurality of pattern electrodes to supply a high-level pattern voltage to at least one pattern electrode among the plurality of pattern electrodes so that an electric field is formed between the plurality of pattern electrodes, wherein the thin-film coating controller selectively supplies the high-level pattern voltage to the at least one pattern electrode based on pattern information including a type of the dispensing material, a pattern design structure, or a step structure of the fabrication substrate.

According to an embodiment of the present disclosure, an apparatus for fabricating a display device comprises a loading plate having a plurality of pattern electrodes arranged in a matrix on a front surface, wherein a fabrication substrate is loaded on the front surface of the loading plate where the plurality of pattern electrodes is arranged, at least one dispenser for dispensing a liquid dispensing material on the fabrication substrate, and a thin-film coating controller disposed on a rear surface of the loading plate and connected to the plurality of pattern electrodes to supply a high-level pattern voltage to at least one pattern electrode among the plurality of pattern electrodes so that an electric field is formed between the plurality of pattern electrodes, wherein the loading plate comprises a plurality of plate blocks connected with or separated from one another in a planar form to conform to a planar shape and size of the fabrication substrate, and wherein the thin-film coating controller selectively supplies the high-level pattern voltage to the at least one pattern electrode based on pattern information including a type of the dispensing material, a pattern design structure, or a step structure of the fabrication substrate.

According to embodiments of the present disclosure, by uniformly flattening the materials dispensed and coated on a fabrication substrate to form a thin film, the fabrication quality of a display panel can be improved, and the occurrence of image display defects can be prevented.

In addition, a thin film can be selectively formed in partial regions of a fabrication substrate, and the influence on the fabrication substrate due to level differences on the plane can be reduced to form a flat thin film, thereby reducing the fabrication process steps and time required for producing the display panel. As a result, the fabrication efficiency can be improved.

It should be noted that effects of the present disclosure are not limited to those described above and other effects of the present disclosure will be apparent to those skilled in the art from the following descriptions.

### BRIEF DESCRIPTION OF THE DRAWINGS

The above and other features of the present disclosure will become more apparent by describing in detail embodiments thereof with reference to the attached drawings.

FIG. 1 is a side view of an apparatus for fabricating a display panel according to an embodiment of the present disclosure.

FIG. 2 is a top view schematically showing the apparatus for fabricating the display panel shown in FIG. 1.

FIG. 3 is a front view schematically showing the apparatus for fabricating the display panel shown in FIG. 1.

FIG. 4 is a transparent perspective view schematically showing the configuration and structure of a loading plate according to an embodiment of the present disclosure.

FIG. 5 is a cross-sectional view showing the cross-sectional structure of the loading plate shown in FIG. 4 in the first direction according to an embodiment.

FIG. 6 is a cross-sectional view showing the cross-sectional structure of the loading plate shown in FIG. 4 in the first direction according to an embodiment.

FIG. 7 is a circuit diagram showing a line connection structure of the pattern electrodes shown in FIG. 4.

FIG. 8 is a cross-sectional view showing materials applied on a fabrication substrate with pattern electrodes in a floating state.

FIG. 9 is a cross-sectional view showing materials applied on a fabrication substrate when a high-level pattern voltage is applied to the pattern electrodes.

FIG. 10 is a plan view schematically showing the configuration and structure of a loading plate according to an embodiment of the present disclosure.

FIG. 11 is a cross-sectional view of the structure taken along a line I-I′ of FIG. 10, showing a dispensing material on a fabrication substrate.

FIG. 12 is a cross-sectional view showing dispensing materials on a fabrication substrate when a high-level pattern voltage is selectively applied to the pattern electrodes for each of plate blocks.

FIG. 13 is a cross-sectional view showing materials applied on a fabrication substrate having level differences with pattern electrodes in a floating state.

FIG. 14 is a cross-sectional view showing materials applied on a fabrication substrate with level differences when a high-level pattern voltage is selectively applied to pattern electrodes for each plate block.

### DETAILED DESCRIPTION OF THE EMBODIMENTS

The present disclosure will now be described more fully hereinafter with reference to the accompanying drawings, in which embodiments of the present disclosure are shown. This disclosure may, however, be embodied in different forms and should not be construed as limited to the embodiments set forth herein. Rather, these embodiments are merely provided to ensure the completeness of the present disclosure, and will fully convey the scope of the present inventive concept to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be partially or entirely combined with each other and technically interwork with each other in various ways. Each embodiment may be implemented independently from each other or may be implemented together in association with each other.

Hereinafter, embodiments according to the present disclosure will be described with reference to the accompanying drawings.

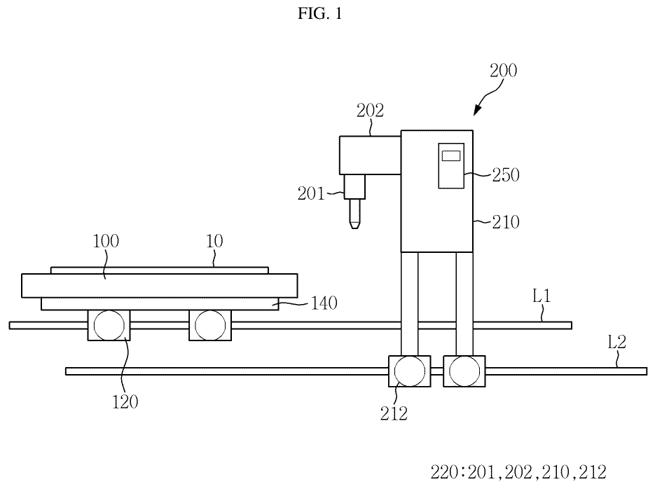

FIG. 1 is a side view of an apparatus for fabricating a display panel according to an embodiment of the present disclosure.

Referring to FIG. 1, the apparatus for fabricating a display panel includes at least one loading plate 100, a thin-film coating controller 140, a loading rail L1, at least one dispensing device 200, and a dispensing rail L2. In addition, the apparatus for fabricating a display panel may further include a chamber in which the loading plate 100, the thin-film coating controller 140, the loading rail L1, and at least one dispensing device 200 are disposed.

The chamber provides an internal processing space where fabrication processes are carried out, such as inkjet printing, dispensing, coating, dipping, aligning, laminating, bonding, laser irradiating, and loading/unloading. The chamber may provide the processing space which is vacuum, can be heated up and cooled down, is soundproof, is vibration-free, and is waterproof. To this end, the chamber may further include a vacuum device, an air suction device, a purification device, a heating device, a cooling device, etc.

The loading plate 10 may be a plate on which the fabrication substrate 10 for fabricating a display panel is seated, and may be formed in a disk shape, or a rectangular or square plate shape.

On the loading plate 10, the fabrication substrate 10 for fabricating a display panel, for example, a wafer or a transparent glass substrate, may be seated. In addition, the fabrication substrate 10 may include a pixel circuit substrate for forming a plurality of pixel electrodes, a light-emitting diode substrate, etc.

The loading plate 100 has a plurality of pattern electrodes arranged in a matrix on the side of a seating surface on which the fabrication substrate 10 is seated. The pattern electrodes may be embedded into the side of the seating surface or may be disposed in the front surface of the seating surface. In addition, a dielectric layer may be further formed on the front surface of the seating surface including the pattern electrodes. Each of the pattern electrodes may be formed in a plate-type electrode with a polygonal shape, such as a triangle, a rectangle, a diamond, or a pentagon. Each of the pattern electrodes may be formed in a plate-type electrode, such as a circular shape, an oval shape, or a semicircular shape. The pattern electrodes PE are electrically connected to terminals disposed on at least one side surface or the rear surface of the loading plate 100 through the connection lines embedded into the loading plate 100. The pattern electrodes may form groups each of which may be connected to the respective terminals in series or in parallel, and each of the pattern electrodes may be connected to the terminals in a one to one manner.

The loading plate 100 may be moved by a plate movement module 120 that moves on a loading rail L1 along the loading rail L1. The plate movement module 120, depending on panel fabrication process, moves the loading plate 100 to a loading position of the fabrication substrate 10, process positions such as dispensing, lamination and laser irradiation, and an unloading position of the fabrication substrate 10. The plate movement module 120 may include at least one motor, a microprocessor, a drive shaft, a rotation shaft, a belt, a chain, a gear, a wheel, etc.

The loading rail L1 forms a movement path for the at least one loading plate 100, the plate movement module 120, and at least one fabrication process device such as an alignment device, or a lamination device. The loading rail L1 may be formed in a conveyor belt system or a transfer robot instead of a simple rail.

The thin-film coating controller 140 selectively supplies a high-level pattern voltage to groups of the pattern electrodes connected in series or parallel in the loading plate 100. The thin-film coating controller 140 may select the pattern electrodes of the loading plate 100 and supply a high-level pattern voltage to each of the pattern electrodes one by one.

The thin-film coating controller 140 may selectively supply a high-level pattern voltage to the groups of pattern electrodes connected with one another through terminals of the loading plate 100 and connection lines. Depending on the connection structure between the pattern electrodes and the terminals, the pattern electrodes of the loading plate 100 may be selected, and a high-level pattern voltage may be supplied to each of the pattern electrodes one by one.

The thin-film coating controller 140 may be disposed inside or outside the chamber separately from the loading plate 100. For example, the thin-film coating controller 140 may be disposed on the rear surface or one side surface of the loading plate 100. The thin-film coating controller 140 may be disposed on either side surface of the loading rail L1 or the plate movement module 120.

The thin-film coating controller 140 is electrically connected to the terminals formed on one side surface, the rear surface, etc. of the loading plate 100. The thin-film coating controller 140 receives a supply voltage through an external power supply unit and changes the magnitude of the supply voltage to generate a high-level pattern voltage.

The thin-film coating controller 140 receives, from an external main control system, etc., and stores pattern information and voltage setting information according to a pattern design structure, a step structure, and the type of the dispensing material of the fabrication substrate 10. The thin-film coating controller 140 changes the magnitude of the supply voltage to the magnitude of the high-level pattern voltage according to the voltage setting information. According to the pattern information, the groups of the pattern electrodes connected with one another are selected or the pattern electrodes are selected one by one, and a high-potential pattern voltage is supplied to the selected pattern electrodes.

The dispensing device 200 may include a dispenser that applies liquid insulating materials such as organic or inorganic materials, an ink, water, an adhesive material, a seal material, photoresist, etc., or a printing device that performs an inkjet printing process. In the following description, a dispenser for applying an insulating material or a liquid material such as an ink and a photoresist will be described as an example. The type, form and usage of the dispensing device 200 are not limited to the embodiments of the present disclosure.

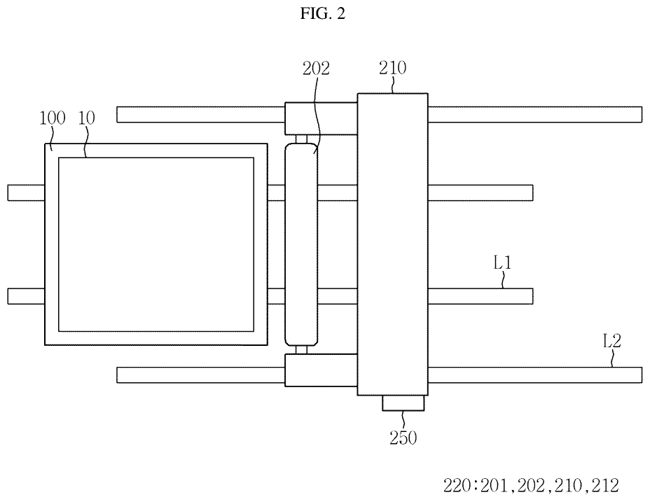

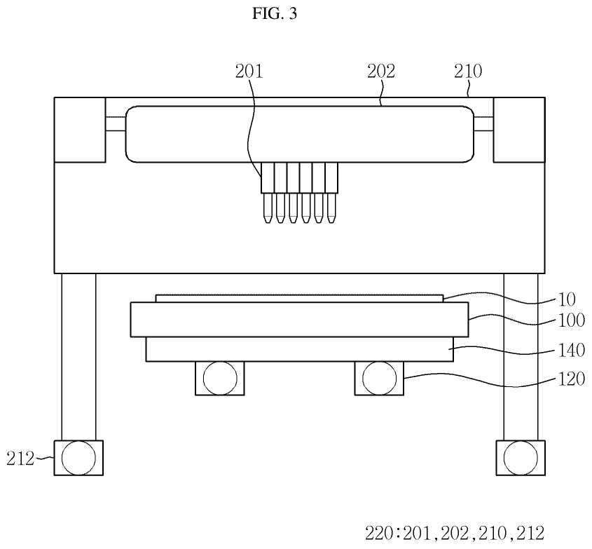

FIG. 2 is a top view schematically showing the apparatus for fabricating the display panel shown in FIG. 1. FIG. 3 is a front view schematically showing the apparatus for fabricating the display panel shown in FIG. 1.

Referring to FIGS. 2 and 3, the dispensing device 200 includes at least one dispenser 220.

At least one dispenser 220 dispenses a liquid dispensing material onto the fabrication substrate 10 of the loading plate 100 during the fabrication process.

At least one dispenser 220 includes a plurality of dispensing headers 201, at least one pump 202, at least one tank 210, and a dispenser movement module 212.

The plurality of dispensing headers 201 may be disposed on one side of the at least one pump 202 and the tank 210, and may be fixed such that they are connected to the tank 210 by the at least one pump 202 and a fixing frame, etc. These dispensing headers 201 dispense the dispensing material supplied through the at least one pump 202 in the direction in which the dispensing headers 201 are arranged.

The plurality of dispensing headers 201 is fixed toward the dispensing process direction and process position where the loading plate 100 and the fabrication substrate 10 are disposed. The dispensing headers 201 dispense the dispensing material supplied through the at least one pump 202 onto the fabrication substrate 10 of the loading plate 100, which is transferred to the dispensing process position during the fabrication process.

The plurality of dispensing headers 201 may dispense liquid dispensing materials in the form of continuous streams or droplets or may dispense them in a fine spray method depending on a predetermined dispensing scheme.

At least one pump 202 supplies the dispensing material stored in at least one tank 210 to the plurality of dispensing headers 201. At least one pump 202 supplies the dispensing material to the plurality of dispensing headers 201 during predetermined fabrication process period and concentration detection period, and controls the dispensing operation so that the dispensing material is dispensed through the dispensing headers 201 in accordance with the predetermined fabrication process period and concentration detection period.

The dispenser movement module 212 moves the at least one tank 210, the at least one pump 202 and the plurality of dispensing headers 201 along the dispensing rail L2. Specifically, the dispenser movement module 212 moves at least one dispenser 220 to a dispensing process position or a concentration detection position for the predetermined fabrication process period and unloading period of the fabrication substrate 10. The dispenser movement module 212 may include at least one motor, a microprocessor, a drive shaft, a rotation shaft, a belt, a chain, a gear, a wheel, etc.

The dispensing rail L2 forms a movement path for at least one fabrication process device, such as at least one dispenser 220. The dispensing rail L2 may be formed in a conveyor belt system or a transfer robot instead of a simple rail.

FIG. 4 is a transparent perspective view schematically showing the configuration and structure of a loading plate according to an embodiment of the present disclosure.

Referring to FIG. 4, the loading plate 100 includes a base plate 101, a plurality of pattern electrodes PE, a plurality of electrical terminals SE, and a plurality of connection lines IL. In addition, the loading plate 100 may further include a dielectric layer 102 formed to cover the entire base plate 101 including the plurality of pattern electrodes PE.

The base plate 101 is formed as a flat plate in a circular shape, or in a polygonal shape such as a rectangle or a square. According to the embodiment of the present disclosure, the base plate 101 is shown as a square flat plate where the front surface (or upper surface) is formed as a square plane. It should be understood, however, that the shape of the base plate 101, when viewed from the top, is not limited to a polygonal shape such as a square, but may be formed as a circular plate, oval, or semicircular type of flat plate.

The plurality of pattern electrodes PE is arranged in a matrix on the front side (e.g., a seating surface) of the base plate 101 on which the fabrication substrate 10 is seated. For example, the pattern electrodes PE may be arranged and disposed in parallel in the first direction (e.g., the x-axis direction or row direction) and the second direction (e.g., y-axis direction or column direction) at the same spacing. The plurality of pattern electrodes PE may be disposed in the front surface of the base plate 101 or may be embedded in the front side of the base plate 101.

Each of the pattern electrodes PE may be formed as a plate-type electrode in a polygonal shape such as a triangle, a rectangle, a diamond, or a pentagon. Each of the pattern electrodes PE may be formed as a disc-type electrode in a circular shape, an oval shape, or a semicircular shape.

The electrical terminals SE are disposed to be exposed on at least one side surface or the rear surface of the base plate 101, and are electrically connected to the thin-film coating controller 140 through connection terminals and cables connected to the electrical terminals SE.

The connection lines IL are connected in series or in parallel to each group of the pattern electrodes PE so that the pattern electrodes PE form the respective groups. These connection lines IL electrically connect each group of the pattern electrodes to at least one electrical terminal SE among the plurality of electrical terminals SE.

The plurality of connection lines IL may be connected in series or in parallel to the pattern electrodes PE arranged in the first direction so that the pattern electrodes PE arranged in the first direction (e.g., the x-axis direction or the row direction) form the respective groups. Each of the connection lines IL is connected in series or parallel to the pattern electrodes PE that form each respective group. One end of each of the connection lines IL is connected to an electrical terminal SE from which a low-level voltage is applied, and the other end thereof is electrically connected to another electrical terminal SE from which a high-level pattern voltage is applied.

The dielectric layer 102 is formed to cover the entire base plate 101 including the plurality of pattern electrodes PE. The dielectric layer 102 may be formed of an insulating organic or inorganic material such as SiO₂ or SiNx to insulate the plurality of pattern electrodes PE from the fabrication substrate 10.

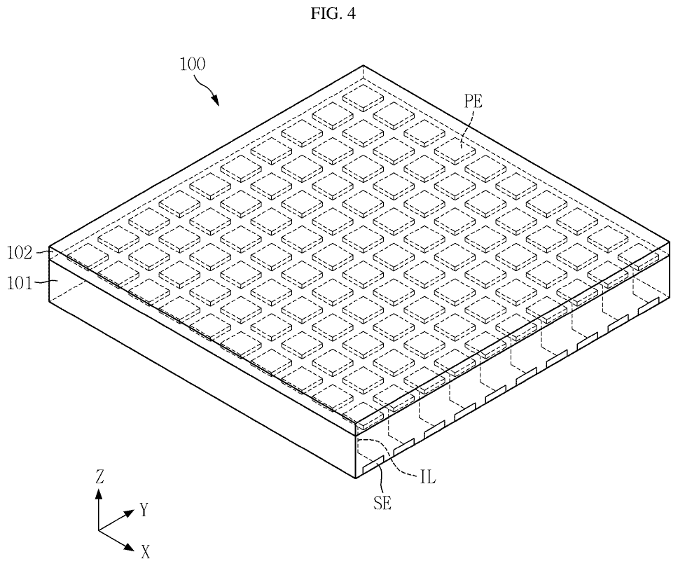

FIG. 5 is a cross-sectional view showing the cross-sectional structure of the loading plate shown in FIG. 4 in the first direction according to an embodiment.

Referring to FIG. 5, a plurality of pattern electrodes PE may be embedded in the base plate 101 on the front side. In this instance, the front surface of the base plate 101 may be flat without level differences due to the pattern electrode PE, etc. The dielectric layer 102 is formed to cover the entire base plate 101 including the plurality of pattern electrodes PE to provide a flat surface.

The pattern electrodes PE are electrically connected to the electrical terminals SE disposed on at least one side surface or the rear surface of the loading plate 100 through the connection lines IL embedded in the loading plate 100. The pattern electrodes PE may form the respective groups in the first or second direction and may be connected to other adjacent pattern electrodes PE in series or in parallel.

The connection lines IL may be connected, in series or in parallel, to the pattern electrodes PE which form each group. For example, as shown in FIG. 5, the connection lines IL may be connected in series with the pattern electrodes PE arranged in parallel in the first direction so that the pattern electrodes PE arranged in parallel in the first direction (e.g., the x-axis direction or the row direction) form the respective groups. In this instance, one end of each of the connection lines IL connected in series with each group of the pattern electrodes PE may be connected to one of the electrical terminals SE from which the low-level voltage is applied, and the other end thereof may be electrically connected to another electrical terminal SE from which the high-level pattern voltage is applied.

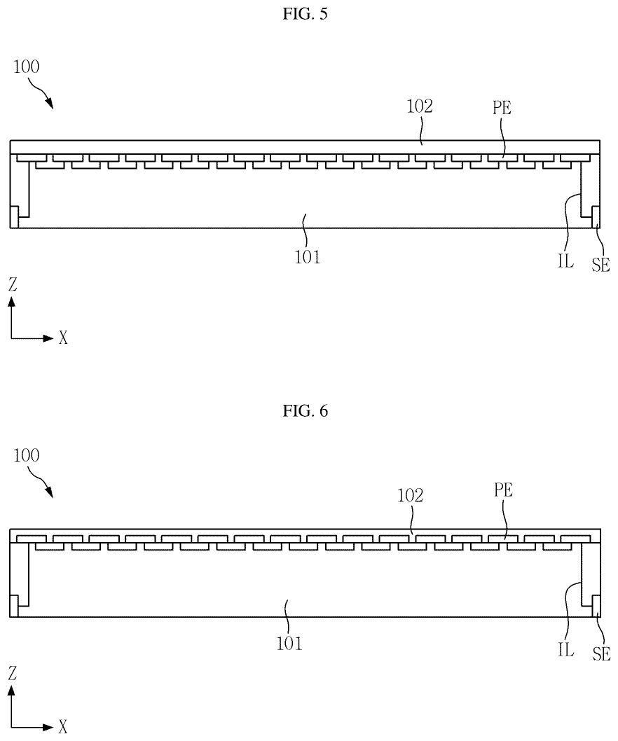

FIG. 6 is a cross-sectional view showing the cross-sectional structure of the loading plate shown in FIG. 4 in the first direction according to an embodiment.

Referring to FIG. 6, a plurality of pattern electrodes PE may be disposed on the front surface of the base plate 101. In this instance, there may be level differences on the front surface of the base plate 101 due to the pattern electrode PE, etc.

The dielectric layer 102 is formed to cover the entire front surface of the base plate 101 including the plurality of pattern electrodes PE to provide a flat surface so that the front surface of the base plate 101 is flat.

The connection lines IL may be connected to the pattern electrodes PE which form each group in series or in parallel. For example, as shown in FIG. 6, the connection lines IL may be connected in series with the pattern electrodes PE arranged in parallel in the first direction so that the pattern electrodes PE arranged in parallel in the first direction (e.g., the x-axis direction or the row direction) form the respective groups. In this instance, one end of each of the connection lines IL connected in series with each group of the pattern electrodes PE may be connected to one of the electrical terminals SE from which the low-level voltage is applied, and the other end thereof may be electrically connected to another electrical terminal SE from which the high-level pattern voltage is applied.

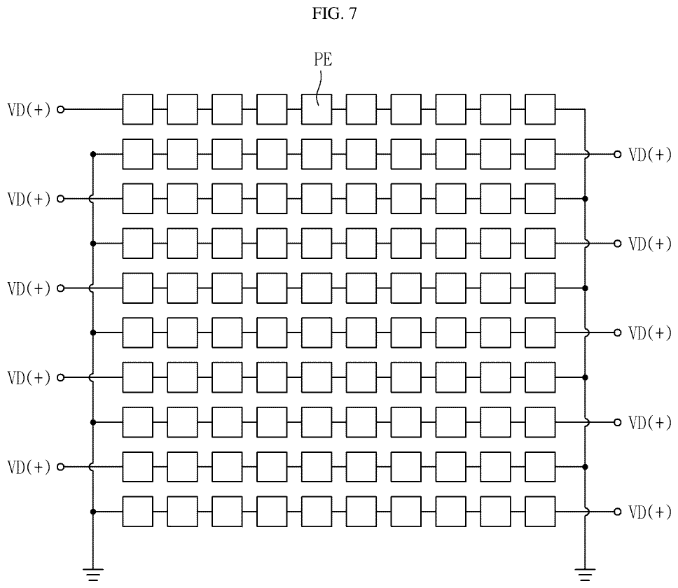

FIG. 7 is a circuit diagram showing a line connection structure of the pattern electrodes shown in FIG. 4.

Referring to FIG. 7, a plurality of pattern electrodes PE may be arranged and disposed in parallel in the first direction (e.g., the x-axis direction or row direction) and the second direction (e.g., the y-axis direction or column direction) at the same spacing.

The plurality of connection lines IL may be connected in series or in parallel to the pattern electrodes PE arranged in parallel in the first direction so that the pattern electrodes PE arranged in parallel in the first direction form the respective groups.

One end of each of the connection lines IL connected in series with each group of the pattern electrodes PE is connected to at least one electrical terminal SE from which a ground voltage or a low-level voltage is applied. On the other hand, the other end of each of the of the connection lines IL connected in series with each group of the pattern electrodes PE is electrically connected to another electrical terminal SE from which a high-level pattern voltage VD(+) is applied.

Among the connection lines IL connected to the groups of pattern electrodes PE arranged in the first direction, one end of each of the connection lines IL of the groups arranged in the odd-numbered rows, i.e., the 2(n−1) th groups, may be connected to at least one electrical terminal SE from which a ground voltage or low-level voltage is applied, while the other end thereof may be electrically connected to another electrical terminal SE from which a high-level pattern voltage VD(+) is applied, where n is a positive integer.

On the other hand, among the connection lines IL connected to the groups of pattern electrodes PE arranged in the first direction, the other end of each of the connection lines IL of the groups arranged in the even-numbered rows, i.e., the 2n^{th} groups, may be connected to at least one electrical terminal SE from which a ground voltage or low-level voltage is applied, while one end thereof may be electrically connected to another electrical terminal SE from which a high-level pattern voltage VD(+) is applied, where n is a positive integer.

The pattern electrodes PE in the 2(n−1) th groups and the pattern electrodes PE in the adjacent 2n^{th} groups may receive the high-level pattern voltage VD(+) in the opposite directions.

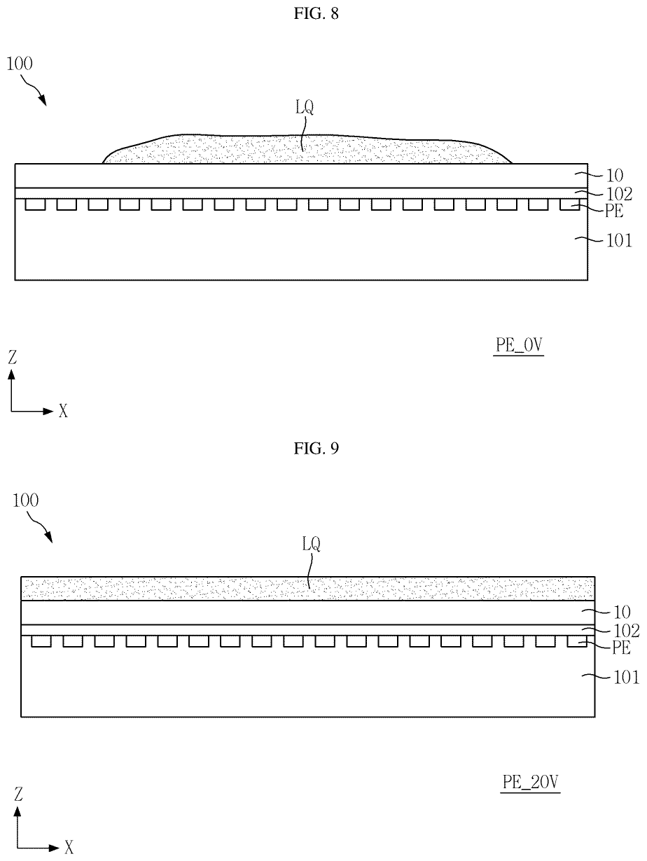

FIG. 8 is a cross-sectional view showing materials applied on a fabrication substrate with pattern electrodes in a floating state.

Referring to FIG. 8, the loading plate 100 may be moved by a plate movement module 120 that moves along the loading rail L1. The fabrication substrate 10 is seated on the loading plate 100.

At least one dispenser 220 of the dispensing device 200 dispenses liquid dispensing materials LQ on the fabrication substrate 10 through a plurality of dispensing headers 201.

Due to the fabrication environment such as a difference in surface energy between the loading plate 100 and the fabrication substrate 10, the dispensing materials LQ applied on the fabrication substrate 10 may not maintain a flat level uniformly. In particular, when the high-level pattern voltage VD(+) is not applied to each group of the pattern electrodes PE and the pattern electrodes PE are in a floating state, the dispensing materials LQ may stick together or move together depending on the processing environment. As a result, the thickness and flatness of the thin film formed on the fabrication substrate 10 may not be uniform, and there may be level differences.

FIG. 9 is a cross-sectional view showing materials applied on a fabrication substrate when a high-level pattern voltage is applied to the pattern electrodes.

Referring to FIG. 9, the thin-film coating controller 140 supplies a high-level pattern voltage VD(+) to the pattern electrodes PE which form at least one group among the plurality of groups of the pattern electrodes PE. Herein, the high-level pattern voltage VD(+) may be supplied in the form of direct current or alternating current voltage. For example, the maximum voltage level of the high-level pattern voltage VD(+) may be one of the voltage from approximately 5 V to approximately 30 V.

An electric field is formed over the group of the pattern electrodes PE to which the high-level pattern voltage VD(+) is supplied. Accordingly, there is a difference in electric field between the group of the pattern electrodes PE to which the high-level pattern voltage VD(+) is supplied and the group of the pattern electrodes PE to which the high-level pattern voltage VD(+) is not supplied.

The dispensing material LQ dispensed on the fabrication substrate 10 is influenced by the electric field, causing them to flow as a fluid toward the front side of the groups of pattern electrodes PE to which a larger electric field is generated, i.e., the groups to which the high-level pattern voltage VD(+) is supplied. As a result, the dispensing material LQ is formed flat along the front side of the group of the pattern electrodes PE to which the high-potential pattern voltage VD(+) is supplied. In this manner, the thickness and flatness of the thin film formed on the fabrication substrate 10 can be uniform.

The thin-film coating controller 140 may receive and store in advance pattern information and voltage setting information according to a pattern design structure, a step structure, and the type of the dispensing material of the fabrication substrate 10 from an external main control system, etc.

The thin-film coating controller 140 reduces or amplifies the magnitude of the supply voltage to the magnitude of the high-level pattern voltage VD(+) according to the voltage setting information. Based on the predetermined pattern information according to the pattern design structure, step structure, etc. of the fabrication substrate 10, the group of the pattern electrodes connected with one another are selected or the pattern electrodes are selected one by one. The thin-film coating controller 140 supplies the high-level pattern voltage VD(+) to the electrical terminals SE and the connection lines IL which are electrically connected to the selected pattern electrodes PE or the selected group of pattern electrodes PE.

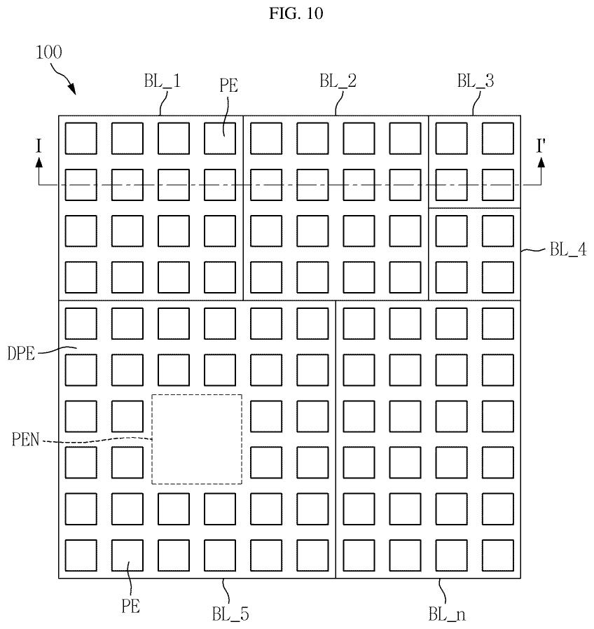

FIG. 10 is a plan view schematically showing the configuration and structure of a loading plate according to an embodiment of the present disclosure.

Referring to FIG. 10, the loading plate 100 includes a plurality of plate blocks BL_1 to BL_n that is connected with or separated from one another in a flat form that conforms to the shape and size of the fabrication substrate 10 when viewed from the top.

Each of the plate blocks BL_1 to BL_n is formed as a flat plate, i.e., in a polygonal shape such as a triangle, a rectangle, a diamond or a square when viewed from the top, with the front surface where the fabrication substrate 10 is seated.

The size or area of the front surface of each of the plate blocks BL_1 to BL_n formed in a polygonal shape may be equal to or different from that of the other plate blocks BL_1 to BL_n disposed adjacently.

The plate blocks BL_1 to BL_n are connected with (or assembled) or separated from one another so that they conform to the shape and area of the rear surface or the planar shape the fabrication substrate 10 disposed on the front surface.

At least one plate block BL_5 among the plate blocks BL_1 to BL_n includes an electrode placement area DPE and a non-electrode placement area PEN distinguished from each other on the front surface where the fabrication substrate 10 is seated.

A plurality of pattern electrodes PE is disposed in a matrix in the electrode placement area DPE.

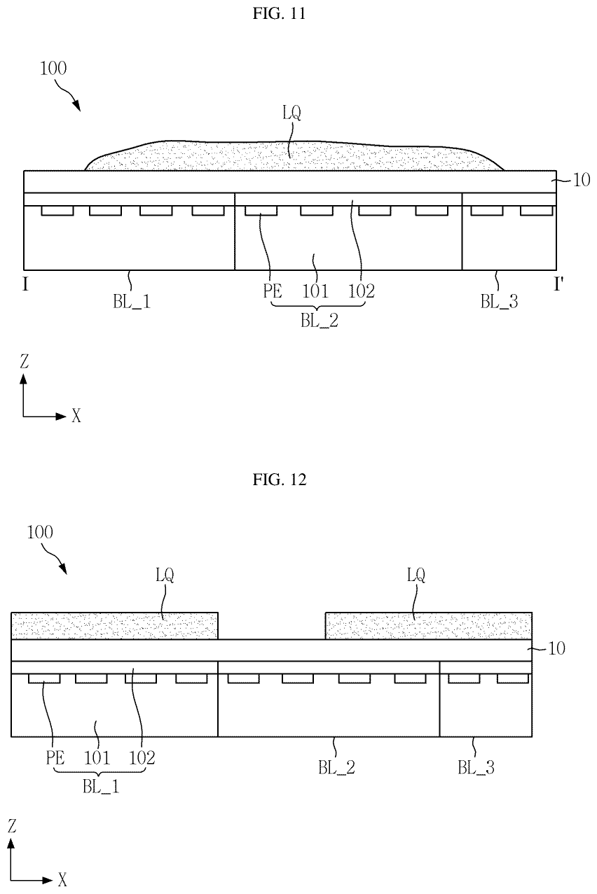

FIG. 11 is a cross-sectional view of the structure taken along a line I-I′ of FIG. 10, showing a dispensing material on a fabrication substrate.

Referring to FIG. 11, each of the plate blocks BL_1 to BL_n includes a base plate 101, a plurality of pattern electrodes PE, a plurality of electrical terminals SE, and a plurality of connection lines IL.

In addition, each of the plate blocks BL_1 to BL_n may further include a dielectric layer 102 formed to cover the entire base plate 101 including the plurality of pattern electrodes PE.

The base plate 101 of each of the plate blocks BL_1 to BL_n is formed as a flat plate in a polygonal shape such as a rectangle, or a square. In the example shown in FIG. 10, the base plate 101 is formed as a square flat plate with the front surface (or upper surface) of a square plane.

The plurality of pattern electrodes PE is arranged in a matrix on the front side (e.g., a seating surface side) of the base plate 101 where the fabrication substrate 10 is seated.

Among the plurality of plate blocks BL_1 to BL_n, at least one plate block BL_5 is divided into the electrode placement area DPE and the non-electrode placement area PEN on the front surface where the fabrication substrate 10 is seated. A plurality of pattern electrodes PE is disposed in a matrix only in the electrode placement area DPE.

The pattern electrodes PE may be arranged and disposed in parallel in the first direction (e.g., the x-axis direction or row direction) and the second direction (e.g., y-axis direction or column direction) at the same spacing. The plurality of pattern electrodes PE may be disposed in the front surface of the base plate 101 or may be embedded in the front side of the base plate 101.

In each of the plate blocks BL_1 to BL_n, the electrical terminals SE are disposed such that they are exposed on at least one side surface or the rear surface of the base plate 101, and are electrically connected to the thin-film coating controller 140 through connection terminals and cables connected to the electrical terminals SE.

The connection lines IL are connected in series or in parallel to each corresponding group of the pattern electrodes PE so that the pattern electrodes PE form the respective groups, and electrically connect each group of the pattern electrodes with at least one of the plurality of electrical terminals SE.

The pattern electrodes PE are electrically connected to the electrical terminals SE disposed on at least one side surface or the rear surface of each of the plate blocks BL_1 to BL_n through the connection lines IL embedded in the plate blocks BL_1 to BL_n. The pattern electrodes PE may form the respective groups in the first or second direction and may be connected to other adjacent pattern electrodes PE in series or in parallel.

The plurality of connection lines IL may be connected in series with the pattern electrodes PE arranged in parallel in the first direction for each of the plurality of plate blocks BL_1 to BL_n so that the pattern electrodes PE arranged in parallel in the first direction (e.g., the x-axis direction or the row direction) form the respective groups. In this instance, one end of each of the connection lines IL connected in series to each group of the pattern electrodes PE may be connected to one of the electrical terminals SE from which the low-level voltage is applied, and the other end thereof may be electrically connected to another electrical terminal SE from which the high-level pattern voltage is applied.

The dielectric layer 102 is formed to cover the entire base plate 101 including the plurality of pattern electrodes PE.

When the fabrication substrate 10 is seated on the loading plate 100 which includes a plurality of plate blocks BL_1 to BL_n connected to each other, the dispenser 220 dispenses liquid dispensing materials LQ onto the fabrication substrate 10 through a plurality of dispensing headers 201.

When the high-level pattern voltage VD(+) is not applied to the pattern electrodes PE which form the respective groups and the pattern electrodes PE in each of the plurality of plate blocks BL_1 to BL_n remain floating, the dispensing materials LQ may stick together or move together depending on the processing environment. As a result, the thickness and flatness of the thin-film formed on the fabrication substrate 10 may not be uniform, and there may be level differences.

FIG. 12 is a cross-sectional view showing dispensing materials on a fabrication substrate when a high-level pattern voltage is selectively applied to the pattern electrodes in each of plate blocks.

Referring to FIG. 12, the thin-film coating controller 140 supplies a high-level pattern voltage VD(+) to at least one group of the pattern electrodes PE among the pattern electrodes PE for each of the plurality of plate blocks BL_1 to BL_n.

An electric field is formed over the group of the pattern electrodes PE to which the high-level pattern voltage VD(+) is supplied. Accordingly, there is a difference in electric field between the group of the pattern electrodes PE to which the high-level pattern voltage VD(+) is supplied and the group of the pattern electrodes PE to which the high-level pattern voltage VD(+) is not supplied.

The dispensing material LQ dispensed on the fabrication substrate 10 is influenced by the electric field, causing it to flow as a fluid toward the front side of the groups of pattern electrodes PE to which a larger electric field is generated, i.e., the groups to which the high-level pattern voltage VD(+) is supplied. As a result, the dispensing material LQ is formed flat along the front side of the group of the pattern electrodes PE to which the high-potential pattern voltage VD(+) is supplied. In this manner, the thickness and flatness of the thin film formed on the fabrication substrate 10 can be uniform.

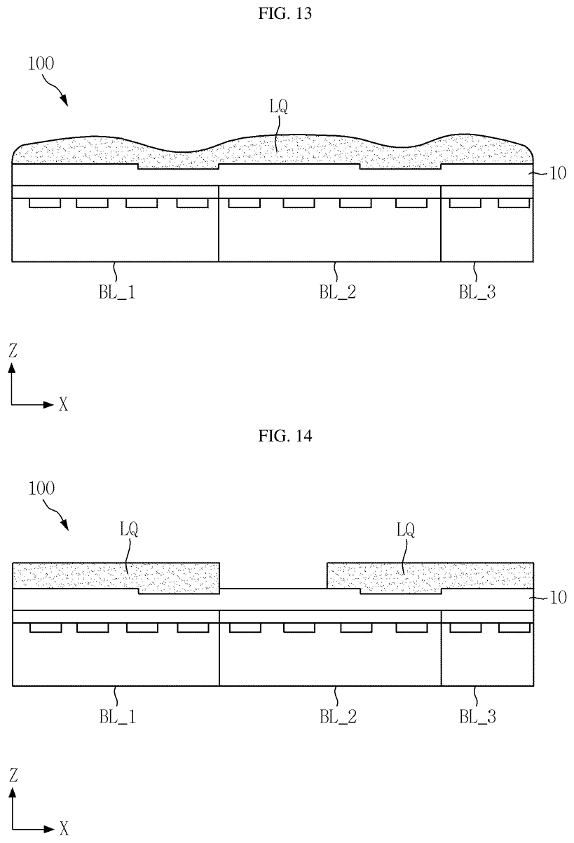

FIG. 13 is a cross-sectional view showing materials applied on a fabrication substrate having level differences with pattern electrodes in a floating state.

Referring to FIG. 13, when the high-level pattern voltage VD(+) is not applied to the pattern electrodes PE which form the respective groups and the pattern electrodes PE in each of the plurality of plate blocks BL_1 to BL_n are remain floating, the dispensing materials LQ may stick together or move together depending on the processing environment. In particular, the dispensing materials LQ may stick together or move according to the pattern design structure and step structure of the fabrication substrate 10. As a result, the thickness and flatness of the thin-film formed on the fabrication substrate 10 may not be uniform, and there may be level differences.

FIG. 14 is a cross-sectional view showing materials applied on a fabrication substrate 10 with level differences when a high-level pattern voltage is selectively applied to pattern electrodes for each plate block.

Referring to FIG. 14, the thin-film coating controller 140 may receive and store in advance pattern information and voltage setting information according to a pattern design structure, a step structure, and the type of the dispensing material of the fabrication substrate 10 from an external main control system, etc.

The thin-film coating controller 140 selects the groups of the pattern electrodes connected with one another for each plate block BL_1 to BL_n or the pattern electrodes one by one based on the predetermined pattern information.

The thin-film coating controller 140 supplies the high-level pattern voltage VD(+) to the electrical terminals SE and the connection lines IL electrically connected to the selected pattern electrodes PE or the selected group of pattern electrodes PE.

The dispensing material LQ dispensed on the fabrication substrate 10 is influenced by the electric field and accordingly flows as a fluid toward the front side of the groups of pattern electrodes PE to which a larger electric field is generated, i.e., the groups to which the high-level pattern voltage VD(+) is supplied. As a result, the dispensing material LQ is formed flat along the front side of the group of the pattern electrodes PE to which the high-potential pattern voltage VD(+) is supplied. In this manner, the thickness and flatness of the thin film formed on the fabrication substrate 10 can be uniform.

In concluding the detailed description, those skilled in the art will appreciate that many variations and modifications can be made to the embodiments of the present disclosure without substantially departing from the principles of the present disclosure. Therefore, the disclosed embodiments of the disclosure are used in a generic and descriptive sense only and not for purposes of limitation.

What is claimed is:

1. An apparatus for fabricating a display device, the apparatus comprising:
a loading plate having a plurality of pattern electrodes arranged in a matrix on a front surface, wherein a fabrication substrate is loaded on the front surface of the loading plate where the plurality of pattern electrodes is arranged;
at least one dispenser for dispensing a liquid dispensing material on the fabrication substrate; and
a thin-film coating controller disposed on a rear surface of the loading plate and connected to the plurality of pattern electrodes to supply a high-level pattern voltage to at least one pattern electrode among the plurality of pattern electrodes so that an electric field is formed between the plurality of pattern electrodes,
wherein the thin-film coating controller selectively supplies the high-level pattern voltage to the at least one pattern electrode based on pattern information including a type of the dispensing material, a pattern design structure, or a step structure of the fabrication substrate.

2. The apparatus of claim 1, wherein the loading plate comprises:
a base plate formed as a flat plate in a circular or polygonal shape;
the plurality of pattern electrodes disposed on a front surface of the base plate where the fabrication substrate is seated;
a plurality of electrical terminals formed on at least one side surface or a rear surface of the base plate; and
a plurality of connection lines connected in series or in parallel with each group of the pattern electrodes, and electrically connecting each group of the pattern electrodes to at least one electrical terminal among the plurality of electrical terminals.

3. The apparatus of claim 2, wherein the loading plate further comprises a dielectric layer formed on the front surface of the base plate which comprises the plurality of pattern electrodes.

4. The apparatus of claim 2, wherein the pattern electrodes are arranged in a matrix in parallel in a first direction and a second direction perpendicular to the first direction, and are arranged at a same spacing, and
wherein the pattern electrodes are arranged on the front surface of the base plate or embedded in the front surface of the base plate.

5. The apparatus of claim 4, wherein the plurality of pattern electrodes is formed as plate-type electrodes having at least one polygonal shape of a triangle, a rectangle, a diamond, a pentagon, a hexagon and an octagon, or as disc-type electrodes having at least one circular shape of a circle, an oval and a semicircle.

6. The apparatus of claim 4, wherein the connection lines are connected in series or in parallel with each group of the pattern electrodes, and electrically connect each group of the pattern electrodes to at least one electrical terminal among the plurality of electrical terminals.

7. The apparatus of claim 6, wherein each group of the pattern electrodes that the connection lines are connected in series or in parallel with is arranged in parallel in the first direction, and
wherein one end of each of the connection lines is connected to an electrical terminal from which a low-level voltage is applied, and another end of the connection lines is electrically connected to another electrical terminal from which a high-level pattern voltage is applied.

8. The apparatus of claim 7, wherein among the connection lines connected to each group of the pattern electrodes arranged in the first direction, a first end of each of the connection lines for the groups of the pattern electrodes arranged along odd-numbered rows is connected to at least one electrical terminal from which a ground voltage or a low-level voltage is applied, and a second end of each of the connection lines for the groups of the pattern electrodes arranged along the odd-numbered rows is electrically connected to another electrical terminal from which a high-level voltage is applied, and
wherein among the connection lines connected to each group of the pattern electrodes arranged in the first direction, a second end of each of the connection lines for the groups of the pattern electrodes arranged along even-numbered rows is connected to at least one electrical terminal from which a ground voltage or a low-level voltage is applied, and a first end of each of the connection lines for the groups of the pattern electrodes arranged along the even-numbered rows is electrically connected to another electrical terminal from which a high-level voltage is applied.

9. The apparatus of claim 4, wherein the thin-film coating controller receives and stores pattern information and voltage setting information according to a pattern design structure, a step structure, and a type of the dispensing material of the fabrication substrate, selects a group of the pattern electrodes or each of the pattern electrodes based on the pattern information, and supplies the high-level pattern voltage to electrical terminals and connection lines electrically connected to the selected pattern electrodes or the selected group of the pattern electrodes.

10. The apparatus of claim 1, wherein the loading plate comprises a plurality of plate blocks connected with or separated from one another in a flat form to conform to a planar shape and size of the fabrication substrate,
wherein each of the plate blocks comprises:
a base plate formed as a flat plate in a circular or polygonal shape;
the plurality of pattern electrodes disposed on a front surface of the base plate where the fabrication substrate is seated;
a dielectric layer formed to cover the front surface of the base plate, the base plate comprising the plurality of pattern electrodes;
a plurality of electrical terminals formed on at least one side surface or a rear surface of the base plate; and
a plurality of connection lines connected in series or in parallel with each group of the pattern electrodes, and electrically connecting each group of the pattern electrodes to at least one electrical terminal among the plurality of electrical terminals.

11. The apparatus of claim 10, wherein the fabrication substrate is seated on a front side of each of the plurality of plate blocks, and the front side of the each of the plurality of plate blocks is formed in at least one polygonal shape selected from a group consisting of a triangle, a rectangle, a diamond, and a square, and
wherein a size or an area of the front side of each of the plate blocks formed in a polygonal shape is identical to or different from that of other adjacent plate blocks.

12. The apparatus of claim 11, wherein at least one plate block among the plurality of plate blocks comprises an electrode placement area and a non-electrode placement area on the front side of the at least one plate block, and
wherein the plurality of pattern electrodes is disposed in a matrix in the electrode placement area.

13. The apparatus of claim 12, wherein the pattern electrodes are arranged in parallel in a first direction and a second direction perpendicular to the first direction at a same spacing in the electrode placement area, and
wherein the pattern electrodes are arranged in the front surface of the base plate or embedded in the front surface of the base plate.

14. The apparatus of claim 13, wherein the connection lines are connected in series or in parallel with each group of the pattern electrodes, and electrically connect each group of the pattern electrodes to at least one electrical terminal among the plurality of electrical terminals.

15. An apparatus for fabricating a display device, the apparatus comprising:
a loading plate having a plurality of pattern electrodes arranged in a matrix on a front surface, wherein a fabrication substrate is loaded on the front surface of the loading plate where the plurality of pattern electrodes is arranged;
at least one dispenser for dispensing a liquid dispensing material on the fabrication substrate; and
a thin-film coating controller disposed on a rear surface of the loading plate and connected to the plurality of pattern electrodes to supply a high-level pattern voltage to at least one pattern electrode among the plurality of pattern electrodes so that an electric field is formed between the plurality of pattern electrodes,
wherein the loading plate comprises a plurality of plate blocks connected with or separated from one another in a flat form to conform to a planar shape and size of the fabrication substrate, and
wherein the thin-film coating controller selectively supplies the high-level pattern voltage to the at least one pattern electrode based on pattern information including a type of the dispensing material, a pattern design structure, or a step structure of the fabrication substrate.

16. The apparatus of claim 15, wherein each of the plurality of plate blocks comprises:
a base plate formed as a flat plate in a circular or polygonal shape;
the plurality of pattern electrodes disposed on a front surface of the base plate where the fabrication substrate is seated;
a dielectric layer formed to entirely cover the front surface of the base plate, the base plate comprising the plurality of pattern electrodes;
a plurality of electrical terminals formed on at least one side surface or a rear surface of the base plate; and
a plurality of connection lines connected in series or in parallel with each group of the pattern electrodes, and electrically connecting each group of the pattern electrodes to at least one electrical terminal among the plurality of electrical terminals.
